(19) United States
(12) Patent Application Publication
(10) Pub. No.: US 2024/0178208 A1
(43) Pub. Date: May 30, 2024

(54) MANUFACTURING METHOD OF LIGHT-EMITTING SUBSTRATE, AND DISPLAY DEVICE

(71) Applicant: TCL CHINA STAR OPTOELECTRONICS TECHNOLOGY CO., LTD., Shenzhen (CN)

(72) Inventor: Hongzhao DENG, Shenzhen (CN)

(73) Assignee: TCL CHINA STAR OPTOELECTRONICS TECHNOLOGY CO., LTD., Shenzhen (CN)

(21) Appl. No.: 18/192,645

(22) Filed: Mar. 30, 2023

(30) Foreign Application Priority Data
Nov. 28, 2022 (CN) 202211504748.6

(51) Int. Cl. H01L 25/16; H01L 23/00

(52) U.S. Cl. CPC H01L 25/167; H01L 24/11; H01L 24/13; H01L 24/81; H01L 24/16; H01L 2224/11003; H01L 2224/1111; H01L 2224/13016; H01L 2224/13111; H01L 2224/16145; H01L 2224/81024; H01L 2224/81815; H01L 2924/12041

(57) ABSTRACT

A manufacturing method of a light-emitting substrate and a display device are provided. The manufacturing method includes: providing a substrate provided with a plurality of electrodes, forming a patterned photoresist layer including openings exposing the electrodes on a surface of the substrate, forming connecting parts in the openings, removing the patterned photoresist layer, and bonding a plurality of light-emitting elements on the connecting parts, wherein slope angles of a plurality of connecting part sidewalls of the connecting parts are ranged between 40° and 140°. The method could improve a yield rate of light-emitting elements bonded to electrodes through connecting parts.

### TECHNICAL FIELD

The present disclosure relates to a field of display technology, and particularly relates to a manufacturing method of a light-emitting substrate and a display device.

### BACKGROUND

New generation of display technology using mini light-emitting diodes is one of hot spots of future display technology. However, at present, one of difficulties in applying the mini light-emitting diodes to display technology is that a bonding yield rate of the mini light-emitting diodes on glass substrates is low.

Therefore, how to improve the bonding yield date of the mini light-emitting diodes on the glass substrates is a technical problem that needs to be solved.

### SUMMARY

A purpose of the present disclosure is to provide a manufacturing method of light-emitting substrate and a display device, which are beneficial to improve a yield rate of light-emitting elements bonded to electrodes through connecting parts.

In a first aspect, the present disclosure provides a manufacturing method of a light-emitting substrate, and the manufacturing method includes:
providing a substrate provided with a plurality of electrodes;
forming a patterned photoresist layer on a surface of the substrate provided with the electrodes, the patterned photoresist layer including a plurality of openings overlapping with the electrodes, and the openings penetrating the patterned photoresist layer and exposing the electrodes;
forming a plurality of connecting parts in the openings;
removing the patterned photoresist layer; and
bonding a plurality of light-emitting elements on the connecting parts to obtain the light-emitting substrate, wherein slope angles of a plurality of connecting part sidewalls of the connecting parts are ranged between 40° and 140°.

In the manufacturing method of the light-emitting substrate of some embodiments, a step of forming the connecting parts in the openings includes:
controlling a filling thickness of the connecting parts in the openings to be less than or equal to a thickness of the patterned photoresist layer.

In the manufacturing method of the light-emitting substrate of some embodiments, the filling thickness of the connecting parts is greater than or equal to 5 μm.

In the manufacturing method of the light-emitting substrate of some embodiments, a thickness of the patterned photoresist layer is ranged between 5 μm and 10 μm.

In the manufacturing method of the light-emitting substrate of some embodiments, the patterned photoresist layer includes an electroplating photoresist.

In the manufacturing method of the light-emitting substrate of some embodiments, slope angles of a plurality of opening sidewalls of the openings are ranged between 40° and 140°.

In the manufacturing method of the light-emitting substrate of some embodiments, the connecting parts include a plurality of solder pastes, and after the removing the patterned photoresist layer and before the bonding the light-emitting elements on the connecting parts, the manufacturing method further includes:
forming a flux in contact with the connecting parts.

In the manufacturing method of the light-emitting substrate of some embodiments, a thickness of the flux is ranged between 3 μm and 7 μm.

In a second aspect, the present disclosure furtherly provides a display device. The display device includes a light-emitting substrate, and the light-emitting substrate includes a substrate provided with a plurality of electrodes, a plurality of connecting parts, and a plurality of light-emitting elements. Wherein the connecting parts are disposed on the electrodes, slope angles of a plurality of connecting part sidewalls of the connecting parts on the substrate is ranged between 40° and 140°, and the light-emitting elements are bonded to the connecting parts.

In the display device of some embodiments, a thickness of the connecting parts is ranged between 5 μm and 10 μm.

Beneficial effects of the present disclosure: In the manufacturing method of the light-emitting substrate and the display device, compared with forming a plurality of tins by stencil printing, forming a patterned photoresist layer on a surface of the substrate provided with electrodes, the patterned photoresist layer including a plurality of openings penetrating the patterned photoresist layer and exposing the electrodes, and forming connecting parts in the openings so that the substrate is provided with the connecting parts, may better ensure an accuracy of the connecting parts on the electrodes, thereby improving a yield rate of light-emitting elements bonded to the electrodes through the connecting parts, and it is beneficial to manufacture the light-emitting substrate with a small distance between the light-emitting elements. Moreover, slope angles of sidewalls of the tins by steel mesh printing are smaller, which may lead to a contact between the tins and lead to a short circuit between the electrodes. While slope angles of connecting part sidewalls of the connecting parts of the light-emitting substrate of the present disclosure on the substrate are ranged between 40° and 140°, a risk of a contact between adjacent connecting parts may be reduced, thereby reducing a risk of a short circuit between the electrodes caused by the contact between the adjacent connecting parts, which is beneficial to improve a display effect of the display device.

In addition, the connecting parts is formed in the opening where the electrode is exposed, the connecting part covers the electrode, and the connecting part may prevent an oxidation of the electrode. Furthermore, compared with difficulty and high cost of forming connecting parts on light-emitting elements, a process of forming the connecting parts in the openings of the patterned photoresist layer in the present disclosure is mature and its cost is low, which is more conductive to a large-scale batch production of light-emitting substrates.

### DESCRIPTION OF DRAWINGS

FIG. 1 is a schematic flow chart of a manufacturing method of a light-emitting substrate according to an embodiment of the present disclosure.

FIG. 2A to FIG. 2H are schematic views of process of manufacturing the light-emitting substrate according to an embodiment of the present disclosure.

FIG. 3 is a schematic cross-sectional view of the light-emitting substrate according to an embodiment of the present disclosure.

FIG. 4 is a schematic view of a display panel according to an embodiment of the present disclosure.

FIG. 5 is a schematic view of a display device according to an embodiment of the present disclosure.

### DETAILED DESCRIPTION OF EMBODIMENTS

The technical solutions in the embodiments of the present disclosure will be described clearly and completely hereafter with reference to the accompanying drawings. Apparently, the described embodiments are only a part of but not all embodiments of the present disclosure. All other embodiments obtained by persons of ordinary skill in the art based on the embodiments of the present disclosure without creative efforts shall fall within the protection scope of the present disclosure.

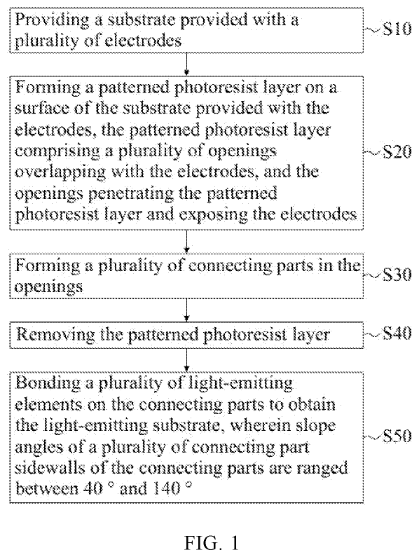

Referring to FIG. 1 which is a schematic flow chart of a manufacturing method of a light-emitting substrate according to an embodiment of the present disclosure, and the manufacturing method includes following steps.

S101, providing a substrate provided with a plurality of electrodes.

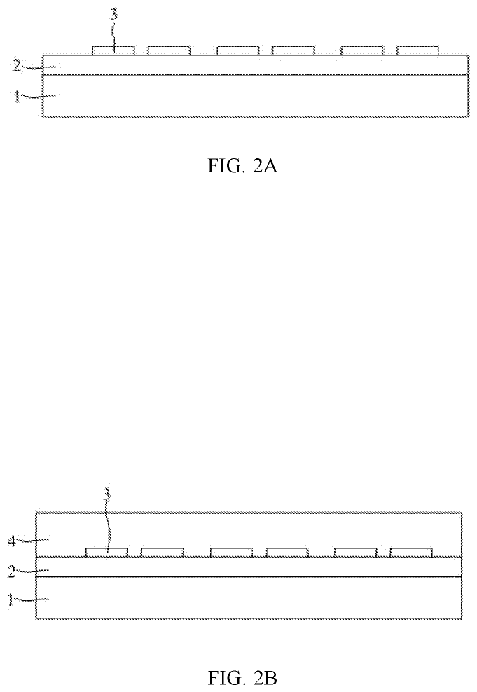

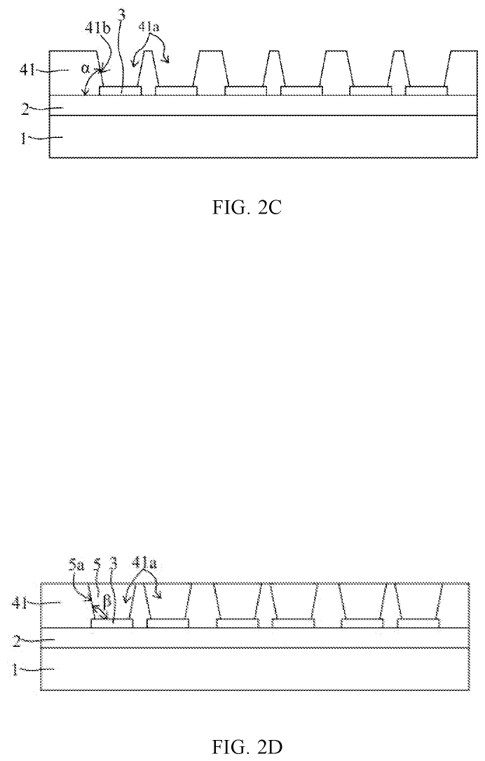

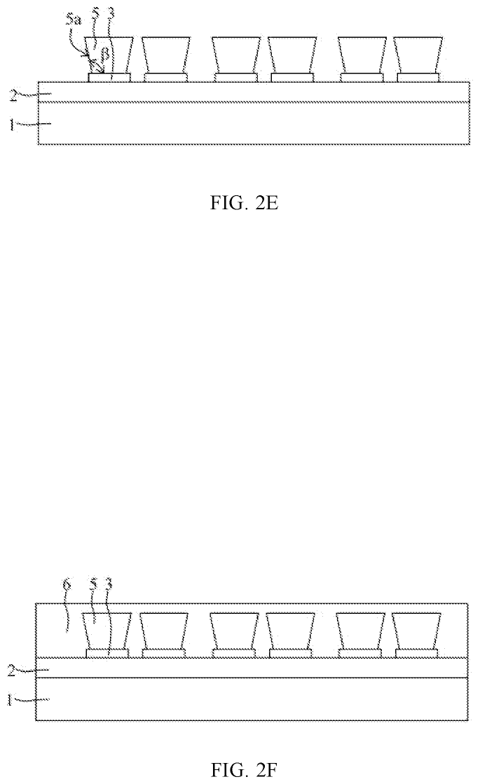

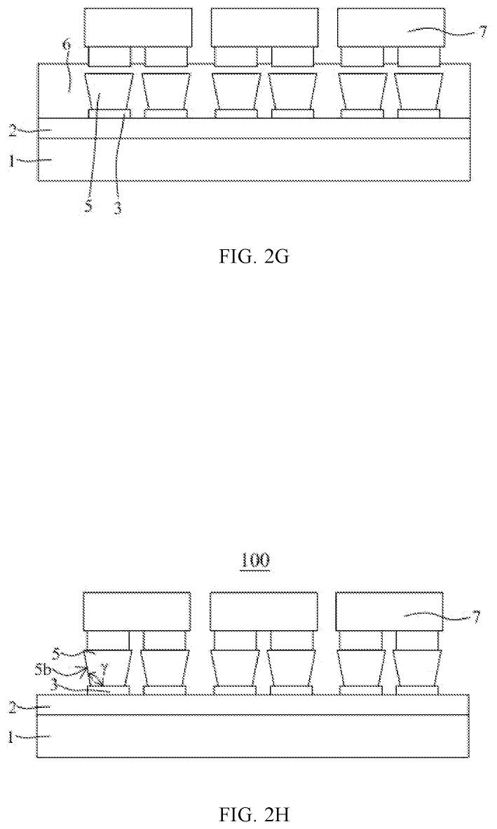

Specifically, as shown in FIG. 2A, providing a substrate 1. A driving circuit layer 2 and a plurality of electrodes 3 are disposed on a surface of the substrate 1. The driving circuit layer 2 is disposed on the surface of the substrate 1, and the plurality of electrodes 3 are disposed on a surface of the driving circuit layer 2 away from the substrate 1.

Wherein the substrate 1 includes a glass substrate, but not limited thereto. The substrate 1 may also include a polymer substrate but not limited to a polyimide substrate.

The driving circuit layer 2 includes a plurality of driving circuits (not indicated in the figure), each of the driving circuits includes a switch element, wirings, and a capacitor, and the plurality of electrodes 3 are connected with the driving circuits. The switch element includes but not limited to a thin film transistor. The thin film transistor includes but not limited to at least one of a metal oxide thin film transistor, a low temperature polycrystalline silicon thin film transistor or an amorphous silicon thin film transistor. The thin film transistor includes but not limited to at least one of a back channel etching type thin film transistor or a back channel protection type thin film transistor.

It can be understood that the switch element such as the thin film transistor may not be disposed, but only data lines and scanning lines are disposed on the substrate 1.

A shape of the electrode 3 is rectangular, but not limited thereto. The shape of the electrode 3 may also be circular, pentagon, hexagon or ellipse. Materials of the electrodes 3 include but not limited to at least one of a molybdenum, an aluminum, a titanium, a copper or a silver.

S102, forming a patterned photoresist layer on the surface of the substrate provided with the electrodes, the patterned photoresist layer including a plurality of openings overlapping with the electrodes, and the openings penetrating the patterned photoresist layer and exposing the electrodes.

Wherein a material of the patterned photoresist layer includes an electroplating photoresist, which is conductive to a thicker thickness of the patterned photoresist layer, thus ensuring a thicker thickness of connecting parts formed in the openings of the patterned photoresist layer, and ensuring that the connecting parts can be connected with light-emitting elements.

In the embodiment, the electroplating photoresist includes a photoresist and a photosensitizer. A material of the photoresist includes but not limited to at least one of polyimide, acrylic acid, and phenolic resin. The photosensitizer includes but not limited to a hexaarylbisimidazole derivative. A performance of the electroplating photoresist resistance to an electroplating solution is strong.

It should be noted that in prior art, a manufacturing process of a display panel is generally provided with an ordinary positive photoresist layer or a negative photoresist layer with a thickness less than 3 microns, and the main reason is that the patterning accuracy of the ordinary positive photoresist layer or the negative photoresist layer with the thickness less than 3 microns can reach 2 microns, which may meet a high accuracy requirement of the prior display panel.

However, the thickness of the ordinary positive photoresist layer or the thickness negative photoresist layer of the prior display panel is too smaller to meet a thickness requirement of the connecting parts to be formed subsequently in the openings of the patterned photoresist layer. And after rich process experience and a plurality of creative experiments, it is found that a plurality of layers of ordinary photoresists cannot be layered in the process, resulting in manufacturing an ordinary photoresist layer with a large thickness being not feasible. After screening a variety of different materials and verifying a variety of different technical solutions, it is finally found that although a patterning accuracy of the electroplating photoresist is relatively low, a thickness of the electroplating photoresist is relatively easy to reach about 10 microns, which could meet the thickness requirements of the connecting parts to be formed subsequently. In addition, a requirement for the patterning accuracy of the connecting parts is lower than those of the metal wiring of the prior display panel, and the electroplating photoresist could meet the thickness requirement of the connecting parts to be formed subsequently.

In addition, based on rich industry experience, the inventor of this application found that at present, in some fields, the electroplating photoresist is mainly applied to resist the corrosivity of the electroplating solution, that is, the electroplating photoresist is used as a protective material. At present, there is no such application: after forming the openings in the electroplating photoresist, forming conductive materials in the openings to obtain thicker conductive materials. In other words, this application is innovative in the application of the electroplating photoresist.

As shown in FIG. 2B, specifically, coating a whole surface of an electroplating photoresist layer 4 covering the plurality of electrodes 3 and the driving circuit layer 2. Then, after the electroplating photoresist layer 4 is exposed and developed in turn, the patterned photoresist layer 41 is obtained. The patterned photoresist layer 41 includes the openings 41a that penetrates the patterned photoresist layer 41 and exposes the electrodes 3, as shown in FIG. 2C. Wherein a light source for the exposure process is a laser with a wavelength ranging from 410 nm to 430 nm.

In the embodiment, the opening 41a could expose the entire electrode 3, or the opening 41a covers a part of the electrode 3 and exposes a part of the electrode 3.

In the embodiment, a thickness of the electroplating photoresist layer 4 is greater than or equal to 5 μm. Accordingly, a thickness of the patterned photoresist layer 41 is greater than or equal to 5 μm, to ensure that a depth of the opening 41a is greater than or equal to 5 μm, which is conducive to the thickness of the connecting parts subsequently formed in the opening 41a, and the thickness of the connecting parts could be greater than or equal to 5 microns, ensuring that the connecting parts could be bonded with the light-emitting elements.

Further, the thickness of the electroplating photoresist layer 4 is less than or equal to 10 μm, and accordingly, the thickness of the patterned photoresist layer 41 is also less than or equal to 10 microns. When the thickness of the electroplating photoresist layer 4 is greater than 10 microns, while the electroplating photoresist layer 4 is difficult to manufacture, it is difficult to control first slope angles α of the opening side walls 41b of the openings 41a of the patterned photoresist layer 41 by exposure and development process, which leads to the difficulty in controlling whether the connecting parts formed in the opening are connected.

It can be understood that the thickness of the electroplating photoresist layer 4 may be ranged between 6 μm and 8 μm, or 6.5 μm and 8.5 μm. Accordingly, the thickness of the patterned photoresist layer 41 may be ranged between 6 μm and 8 μm, or 6.5 μm and 8.5 μm.

For example, the thickness of the electroplating photoresist layer 4 may be 5 μm, 5.5 μm, 6 μm, 6.5 μm, 7 μm, 7.5 μm, 8 μm, 8.5 μm, 9 μm, 9.5 μm or 10 μm. Accordingly, the thickness of the patterned photoresist layer 41 may be 5 μm, 5.5 μm, 6 μm, 6.5 μm, 7 μm, 7.5 μm, 8 μm, 8.5 μm, 9 μm, 9.5 μm or 10 μm.

In the embodiment, a depth of the opening 41a is equal to the thickness of the electroplating photoresist layer 4. The depth of the opening 41 is ranged between 5 μm and 10 μm to ensure that a thickness of the connecting part subsequently formed in the opening 41a is greater than or equal to 5 μm, to ensure that the connecting part may be bonded with the light-emitting element, and to avoid that the depth of the opening 41a is so large that a controlling difficulty of the first slope angles α is increased.

It can be understood that the depth of the opening 41a may be ranged between 6 μm and 8 μm, or 6.5 μm and 8.5 μm.

For example, the depth of the opening 41a may be 5 μm, 5.5 μm, 6 μm, 6.5 μm, 7 μm, 7.5 μm, 8 μm, 8.5 μm, 9 μm, 9.5 μm or 10 μm.

In the embodiment, the first slope angles α of the opening side walls 41b of the openings 41a are ranged between 40° and 140°, which is beneficial to steep side walls of the connecting parts subsequently formed in the opening 41a, and reduce a risk of a short circuit between the electrodes caused by a contact between adjacent connecting parts after the removal of the patterned photoresist layer 41.

It should be noted that when a bottom surface of the patterned photoresist layer 41 corresponding to the opening side wall 41b is flat and the opening sidewall 41b is flat, the first slope angle α is equal to an included angle between the opening sidewall 41b and the corresponding bottom surface, and the bottom surface is in contact with the substrate 1 and intersects with the corresponding opening side wall 41b. When the bottom surface is not flat, taking an intersection point between the opening sidewall 41b and the bottom surface as an intersection point, defining a first auxiliary horizontal bottom surface parallel to a bearing surface of the substrate 1 (a surface of the driving circuit layer 2) and intersecting with the patterned photoresist layer 41, and an included angle between the first auxiliary horizontal bottom surface and the opening sidewall 41b is equal to the first slope angle α. When the opening side wall 41b is a cambered surface, taking an intersection point between the opening side wall 41b and the bottom surface as a tangent point, defining a first auxiliary tangent plane to the opening side wall 41b, and an included angle between the first auxiliary tangent plane and the bottom surface is equal to the first slope angle α. In a same way, when the bottom surface is not flat and the opening side wall 41b is a cambered surface, defining a first auxiliary horizontal bottom surface and a first auxiliary tangent plane respectively by the above method, and an included angle between the first auxiliary horizontal bottom surface and the first auxiliary tangent plane is equal to the first slope angle α.

It can be understood that the first slope angle α may be ranged between 70° and 110°, 80° and 100°, 82° and 108°, or 85° and 95°.

Further, the first slope angle α is ranged between 80° and 100°, which is beneficial to a steep side wall of the connecting part subsequently formed in the opening 41a, and greatly reduce a risk of a short circuit between the electrodes caused by a contact between adjacent connecting parts after the removal of the patterned photoresist layer 41.

Specifically, as shown in FIG. 2C, the first slope angle α is ranged between 80° and 90°, to adapt to a shape of the opening 41a produced by a current exposure and development process, at the same time, it can ensure that the connecting part could be more easily formed in the opening 41a, and the side wall of the connecting part subsequently formed in the opening 41a could be steeper, and the problem of short circuit between the electrodes caused by the connection between the connecting parts could be improved.

It should be noted that the first slope angle α obtained by patterning the electroplating photoresist layer may also be ranged between 0° and 20°, or 160° and 180°. But in order to greatly increase the slope of the side wall of the connecting part subsequently formed in the opening 41a and reduce the risk of the contact between the connecting parts, the first slope angle α prepared in this application is preferably ranged between 40° and 140°.

For example, the first slope angle α may be 40°, 45°, 50°, 55°, 60°, 65°, 70°, 75°, 80°, 81°, 82°, 83°, 84°, 85°, 86°, 87°, 88°, 89°, 90°, 95°, 100°, 105°, 110°, 115°, 120°, 125°, 130°, 135°, or 140°.

In the embodiment, shapes of a cross-section of the openings 41a along a direction perpendicular to the thickness of the patterned photoresist layer 41 are same as shapes of the electrodes 3, so that a shape of a cross-section of the connecting part subsequently formed in the opening 41a are same as the shapes of the electrodes 3 in the direction, so as to ensure that the connecting part could be accurately formed on the electrode 3.

Specifically, the shape of the opening 41a is a rectangle, but not limited to thereto, and the shape of the opening 41a could also be a circle, a pentagon, a hexagon or an oval.

In the embodiment, the shape of the opening 41a is a rectangle, a trapezoid or an inverted trapezoid. Wherein, when the first slope angle α is ranged between 40° and 90°, the shape of the opening 41a is an inverted trapezoid. When the first slope angle α is equal to 90°, the shape of the opening 41a is a rectangle. When the first slope angle α is ranged between 90° and 140°, the shape of the opening 41a is a trapezoid.

S103, forming a plurality of connecting parts in the openings.

The connecting part includes a solder paste, which is a paste mixture composed of a solder powder, a surfactant and a thixotropic agent. Understandably, the connecting part may also be other conductive materials, for example, the connecting part is conductive glue, etc.

Specifically, as shown in FIG. 2D, the connecting part 5 is filled in the opening 41a by one of electroplating, evaporation, or physical vapor deposition.

In the embodiment, a filling thickness of the connecting part 5 in the opening 41a is less than or equal to the thickness of the patterned photoresist layer 41, to avoid the connecting parts 5 in different openings 41a spilling out and connecting, and resulting in short circuit between the electrode 3.

Specifically, as shown in FIG. 2D, the filling thickness is equal to the thickness of the patterned photoresist layer 41, and the shape of the connecting part 5 is same as that of the opening 41a.

Wherein the thickness of the connecting part 5 is greater than or equal to 5 microns, so as to ensure that the connecting parts 5 could be subsequently bonded with the light-emitting elements, and improve the bonding yield between the connecting parts 5 and the light-emitting elements.

Further, the thickness of the connecting part 5 is less than or equal to 10 microns to avoid that the thickness of the connecting part 5 is too thick, which makes it difficult to manufacture the electroplating photoresist layer 4. At the same time, the first slope angle α is difficult to control, resulting in the slope angle of the side wall of the connecting part 5 being difficult to control.

It can be understood that the thickness of the connecting part 5 may be ranged between 6 microns and 8 microns, or 6.5 microns and 8.5 microns.

For example, the thickness of the connecting part 5 may be 5 μm, 5.5 μm, 6 μm, 6.5 μm, 7 μm, 7.5 μm, 8 μm, 8.5 μm, 9 μm, 9.5 μm or 10 μm.

In the embodiment, a sum of a second slope angle β of a first connecting part side wall 5a of the connecting part 5 in the opening 41a and the first slope angle α is equal to 180°. When the first slope angle α is ranged between 40° and 140°, accordingly, the second slope angle β is ranged between 40° and 140°.

It should be noted that when a first bottom surface of the connecting part 5 contacting with the electrode 3 is flat and the first connecting part side wall 5a is flat, the second slope angle β is equal to an included angle between the first bottom surface and the first connecting part side wall 5a. When the first bottom surface is not flat, taking an intersection point between the first bottom surface and the first connecting part side wall 5a as an intersection point, defining a second auxiliary horizontal bottom surface parallel to the bearing surface of the substrate 1 and intersecting with the first connecting part 5, and an included angle between the second auxiliary horizontal bottom surface and the first connecting part side wall 5a is equal to the second slope angle β. When the first connecting part side wall 5a is a cambered surface, taking an intersection point between first bottom surface and the first connecting part side wall 5a as a tangent point, defining a second auxiliary tangent plane to the first connecting part side wall 5a, and an included angle between the second auxiliary tangent plane and the first bottom is equal to the second slope angle β. In a same way, when the first bottom surface is not flat and the first connecting part side wall 5a is a cambered surface, defining a second auxiliary horizontal bottom surface and a second auxiliary tangent plane respectively by the above method, and an included angle between the second auxiliary horizontal bottom surface and the second auxiliary tangent plane is equal to the second slope angle β.

It can be understood that the second slope angle β may be ranged between 60° and 120°, 70° and 110°, 80° and 100°, or 85° and 95°.

For example, the second slope angle β may be 40°, 45°, 50°, 55°, 60°, 65°, 70°, 75°, 80°, 81°, 82°, 83°, 84°, 85°, 86°, 87°, 88°, 89°, 90°, 92°, 95°, 98°, 100°, 105°, 110°, 115°, 120°, 125°, 130°, 135°, or 140°.

Further, the second slope angle β is ranged between 80° and 100°.

It should be noted that solder pastes printed on electrodes by traditional steel screen printing technology includes gentle slopes, a slope angle of the gentle slope is less than 20°. Adjacent solder pastes are easy to connect, resulting in short circuit between the electrodes.

However, in the present disclosure, by controlling the first slope angle α, the second slope angle β of the connecting part 5 defined by the opening 41a is preferably ranged between 80° and 100°, which is far greater than the slope angle of the connecting part obtained by the steel screen printing, so that the first connecting part side wall 5a of the first connecting part 5 is very steep. It can significantly reduce the risk of the contact between adjacent connecting parts 5, and significantly reduce the risk of the short connection between the electrodes 3.

Specifically, the first slope angle α is ranged between 80° and 90°, and the second slope angle β is ranged between 90° and 100°.

S104, removing the patterned photoresist layer.

Specifically, as shown in FIG. 2E, firstly, peel to remove the patterned photoresist layer 41.

Finally, forming a flux in contact with the connecting parts 5 by a coating or printing process. Specifically, forming the flux 6 covering the connecting part 5 and the driving circuit layer 2 by the printing process, as shown in FIG. 2F. Wherein the printing process includes but not limited to a steel screen printing.

Wherein the flux 6 is used to reduce the solder paste melting point, and the flux 6 is also a paste. Materials for the flux 6 include a rosin. A thickness of the flux 6 is ranged between 3 μm and 7 μm. If the thickness of the flux 6 is less than 3 μm, it will lead to incomplete melting of the solder paste and poor adhesion of the solder paste. If the thickness of the flux 6 is greater than 7 μm, it will cause the connecting part to melt and spread out, and the adjacent connecting parts being connected will cause a short circuit between the adjacent electrodes.

It can be understood that the thickness of the flux 6 may be ranged between 4 μm and 6 μm.

For example, the thickness of the flux 6 may be 3 μm, 3.5 μm, 4 μm, 4.5 μm, 5 μm, 5.5 μm, 6 μm, 6.5 μm, or 7 μm.

S105, bonding a plurality of light-emitting elements on the connecting parts to obtain the light-emitting substrate, wherein slope angles of a plurality of connecting part sidewalls of the connecting parts are ranged between 40° and 140°.

Specifically, as shown in FIG. 2G, the light-emitting element 7 is fixed on the flux 6 of the substrate 1 and is corresponding to the connecting part 5. Then, with a reflow welding process and under the action of flux 6, the connecting part 5 is melted and cooled successively. And after that, the connecting part 5 is bonded with pins of the light-emitting element 7 to obtain the light-emitting substrate 100, as shown in FIG. 2H.

Wherein, when the light-emitting element 7 is bonded with the connecting part 5 by the reflow soldering process under the action of the flux 6, the flux 6 which is not bonded with the solder paste is directly volatilized in the reflow welding process, and the solder paste which is bonded with the flux 6 reduces the melting point of the solder paste to make itself melt. After cooling, the solder paste is interlocked with pins of the light-emitting device 7.

In the embodiment, the light-emitting elements are mini light-emitting diodes (Mini LEDs) or micro light-emitting diodes (Micro LEDs).

It can be understood that, during the above step, electronic components besides the light-emitting device 7, such as resistors, capacitors or integrated chips could also be welded to the connecting parts 5.

In the embodiment, since the second slope angle β is ranged between 40° and 140° before the reflow welding process, and the connecting part 5 including the solder paste is difficult to flatten on the electrode 3, the slope angle of the connecting part 5 is difficult to change during the reflow welding process, and the change tendency is that a shape of a side wall of the connecting part 5 tends to be curved. Therefore, after the reflow soldering process, a third slope angle γ is ranged between 40° and 140°, wherein the third slope angle γ is a slop angle of a second connecting part side wall of the second connecting part 5 bonded to the light emitting element 7 on the substrate 1.

It should be noted that the measurement method of the third slope angle γ is the same as that of the second slope angle β, which will not be repeated here.

It can be understood that the third slope angle γ may be ranged between 60° and 120°, 70° and 110°, 80° and 100°, 82° and 108°, or 85° and 95°.

For example, after the reflow soldering process, the third slope angle γ may be 40°, 45°, 50°, 55°, 60°, 65°, 70°, 75°, 80°, 81°, 82°, 83°, 84°, 85°, 86°, 87°, 88°, 89°, 90°, 95°, 100°, 105°, 110°, 115°, 120°, 125°, 130°, 135°, or 140°.

Further, the third slope angle γ is ranged between 80° and 100°, and the third slope angle γ is far greater than a slope angle (less than 20°) of an edge part of the solder paste obtained by the steel mesh printing and the return welding. The second connecting part side wall 5b is steep, which may significantly reduce the risk of the contact between the connecting parts 5, thereby reducing the short circuit between the electrodes 3.

In the manufacturing method of the light-emitting substrate of the disclosure, the electroplating photoresist layer covering the electrodes and the substrate is formed on the substrate. After patterning the electroplating photoresist layer by the exposure and the development, the patterned photoresist layer including the openings is obtained, and the electrodes are exposed by the openings. The openings are filled with a tin paste by one of an evaporation, an electroplating and a physical deposition process. A substrate provided with the tin paste is obtained after removing the patterned photoresist layer. The manufacturing method may better ensure an accuracy of the tin paste on the electrodes, thereby improving a yield rate of light-emitting elements bonded to the electrodes through the tin paste, and it is beneficial to manufacture the light-emitting substrate with a small distance between the light-emitting elements. Moreover, slope angles of sidewalls of the tins by the steel mesh printing are smaller, which may lead to the contact between the tins and lead to the short circuit between the electrodes. While the slope angles of the connecting part sidewalls of the connecting parts of the light-emitting substrate of the present disclosure on the substrate are ranged between 40° and 140°, the risk of the contact between adjacent connecting parts may be reduced, thereby reducing the risk of the short circuit between the electrodes caused by the contact between the adjacent connecting parts, which is beneficial to improve the display effect of the display device.

In addition, the tin paste is formed in the opening where the electrode is exposed, and the tin paste covers the electrode, and the tin paste may prevent an oxidation of the electrode. Furthermore, compared with difficulty and high cost of forming the tin paste on the light-emitting elements, a process of forming the connecting parts in the openings of the patterned photoresist layer in the present disclosure is mature and its cost is low, which is more conductive to a large-scale batch production of light-emitting substrates.

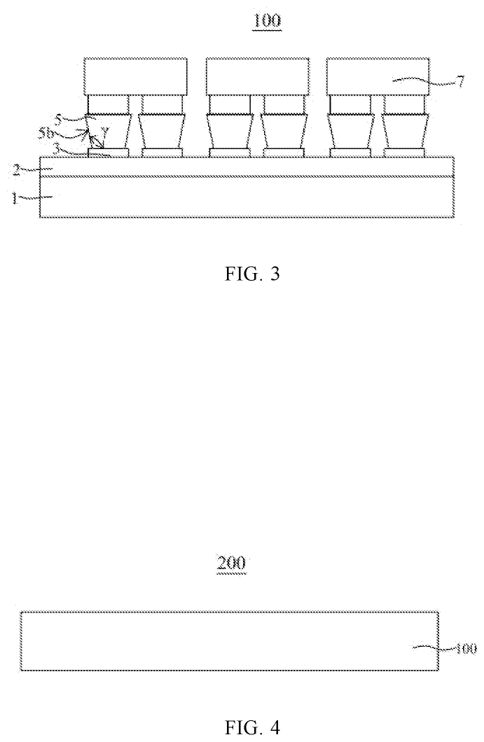

Referring to FIG. 3, FIG. 3 is a schematic cross-sectional view of the light-emitting substrate according to an embodiment of the present disclosure. The light-emitting substrate is obtained by the above manufacturing method.

In the embodiment, the light-emitting substrate includes the substrate 1, the driving circuit layer 2, the electrodes 3, the connecting parts 5, and the light-emitting elements 7.

The driving circuit layer 2 are disposed on a surface of the substrate 1, and a plurality of the electrodes are disposed on a surface of the driving circuit layer 2 away from the substrate 1. The substrate 1 includes a glass substrate. Materials of the electrodes 3 include a copper.

The connecting parts 5 are disposed on the electrodes 3, and bonded with the light-emitting elements 7. The connecting parts 5 include a tin.

A third slope angle γ is ranged between 40° and 140°, wherein the third slope angle γ is a slop angle of a second connecting part side wall of the second connecting part 5 bonded to the light emitting element 7.

It can be understood that the third slope angle γ may be ranged between 60° and 120°, 70° and 110°, 80° and 100°, 82° and 108°, or 85° and 95°.

Further, the third slope angle γ is ranged between 80° and 100°, and the third slope angle γ is far greater than a slope angle (less than 20°) of an edge part of the solder paste obtained by the steel mesh printing and the return welding. The second connecting part side wall 5b is steep, which may significantly reduce the risk of the contact between the connecting parts 5, thereby reducing the short circuit between the electrodes 3.

For example, the third slope angle γ may be 40°, 45°, 50°, 55°, 60°, 65°, 70°, 75°, 80°, 81°, 82°, 83°, 84°, 85°, 86°, 87°, 88°, 89°, 90°, 95°, 100°, 105°, 110°, 115°, 120°, 125°, 130°, 135°, or 140°.

The thickness of the connecting part 5 is greater than or equal to 5 microns, so as to ensure the bonding yield between the connecting parts 5 and the light-emitting elements.

Further, the thickness of the connecting part 5 is less than or equal to 10 microns to make the third slope angle γ easier to control.

In the embodiment, the light-emitting elements 7 are mini light-emitting diodes (Mini LEDs) or micro light-emitting diodes (Micro LEDs).

In the light-emitting substrate of the present disclosure, the third slope angle γ is ranged between 40° and 140°, which could reduce the risk of the contact between the connecting parts 5, and reduce the risk of the short connection between the electrodes 3, thereby improving the luminous effect of the light-emitting substrate.

Referring to FIG. 4, FIG. 4 is a schematic view of a display panel according to an embodiment of the present disclosure. The display panel 200 includes the above light-emitting substrate 100.

Wherein, when the light-emitting element 7 is a Micro LED, the display panel 200 is a Micro LED display panel, and when the light emitting element 7 is a Mini LED, the display panel 200 is a Mini LED display panel.

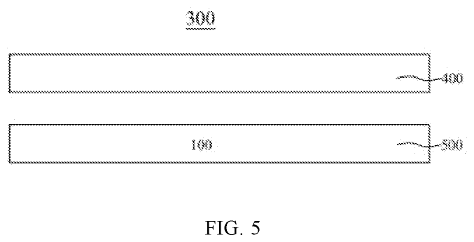

Referring to FIG. 5, FIG. 5 is a schematic view of a display device according to an embodiment of the present disclosure. The display device 300 is a liquid crystal display device. The display device 300 includes a backlight module 500 and a liquid crystal display panel 400, the liquid crystal display panel 400 is located on a light-emitting side of the backlight module 500, and the backlight module 500 includes the light-emitting substrate 100.

The description about the foregoing embodiments is merely provided to help understand the method and core ideas of the present disclosure. Persons of ordinary skill in the art should understand that they may still make modifications to the technical solutions described in the foregoing embodiments or make equivalent replacements to some or all technical features thereof, without departing from the scope of the technical solutions of the embodiments of the present disclosure.

What is claimed is:

1. A manufacturing method of a light-emitting substrate, comprising:
providing a substrate provided with a plurality of electrodes;
forming a patterned photoresist layer on a surface of the substrate provided with the electrodes, wherein the patterned photoresist layer comprises a plurality of openings penetrating the patterned photoresist layer to expose the electrodes;
forming a plurality of connecting parts in the openings;
removing the patterned photoresist layer; and
bonding a plurality of light-emitting elements on the connecting parts to obtain the light-emitting substrate, wherein slope angles of a plurality of connecting part sidewalls of the connecting parts are ranged between 40 degrees and 140 degrees.

2. The manufacturing method of the light-emitting substrate of claim 1, wherein a step of forming the connecting parts in the openings comprises:
controlling a filling thickness of the connecting parts in the openings to be less than or equal to a thickness of the patterned photoresist layer.

3. The manufacturing method of the light-emitting substrate of claim 2, wherein the filling thickness of the connecting parts is greater than or equal to 5 μm.

4. The manufacturing method of the light-emitting substrate of claim 1, wherein a thickness of the patterned photoresist layer is ranged between 5 μm and 10 μm.

5. The manufacturing method of the light-emitting substrate of claim 1, wherein the patterned photoresist layer comprises an electroplating photoresist.

6. The manufacturing method of the light-emitting substrate of claim 1, wherein slope angles of a plurality of opening sidewalls of the openings are ranged between 40 degrees and 140 degrees.

7. The manufacturing method of the light-emitting substrate of claim 6, wherein the slope angles of the opening sidewalls of the openings are greater than or equal to 80 degrees and less than or equal to 100 degrees.

8. The manufacturing method of the light-emitting substrate of claim 1, wherein depths of the openings are ranged between 5 μm and 10 μm.

9. The manufacturing method of the light-emitting substrate of claim 1, wherein shapes of a cross-section of the openings along a direction perpendicular to the thickness of the patterned photoresist layer are same as shapes of the electrodes.

10. The manufacturing method of the light-emitting substrate of claim 9, wherein the shapes of the cross-section of the openings along the direction perpendicular to the thickness of the patterned photoresist layer are rectangle, circle, pentagon, hexagon or ellipse.

11. The manufacturing method of the light-emitting substrate of claim 1, wherein shapes of a cross-section of the openings along a thickness direction of the patterned photoresist layer are rectangle, trapezoid or inverted trapezoid.

12. The manufacturing method of the light-emitting substrate of claim 1, wherein the connecting parts comprise a plurality of solder pastes, and after the removing the patterned photoresist layer and before the bonding the light-emitting elements on the connecting parts, the manufacturing method further comprises:
forming a flux in contact with the connecting parts.

13. The manufacturing method of the light-emitting substrate of claim 12, wherein a thickness of the flux is ranged between 3 μm and 7 μm.

14. A display device comprising a light-emitting substrate, wherein the light-emitting substrate comprises:
a substrate provided with a plurality of electrodes;
a plurality of connecting parts, disposed on the electrodes, slope angles of a plurality of connecting part sidewalls of the connecting parts on the substrate being ranged between 40 degrees and 140 degrees; and
a plurality of light-emitting elements, bonded to the connecting parts.

15. The display device of claim 14, wherein a thickness of the connecting parts is ranged between 5 μm and 10 μm.

16. The display device of claim 14, wherein the slope angles of the connecting part sidewalls of the connecting parts on the substrate are ranged between 40 degrees and 140 degrees.

17. The display device of claim 14, wherein shapes of a cross-section of the connecting parts along a direction perpendicular to a thickness of the substrate are same as shapes of the electrodes.

18. The display device of claim 14, wherein the light-emitting elements are mini light-emitting diodes or micro light-emitting diodes.

19. The display device of claim 14, wherein the display device comprises a backlight module and a liquid crystal display panel located on a light-emitting side of the backlight module, and the backlight module comprises the light-emitting substrate.

20. The display device of claim 14, wherein the connecting parts comprise a plurality of solder pastes.
